(19) United States
(12) Patent Application Publication
(10) Pub. No.: US 2024/0154010 A1
(43) Pub. Date: May 9, 2024

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Meng-Han Chou, Hsinchu (TW); Kuo-Ju Chen, Taichung (TW); Su-Hao Liu, Chiayi (TW); Huicheng Chang, Tainan (TW); Yee-Chia Yeo, Hsinchu (TW)

(21) Appl. No.: 18/099,951

(22) Filed: Jan. 22, 2023

Related U.S. Application Data
(60) Provisional application No. 63/422,942, filed on Nov. 5, 2022.

(51) Int. Cl. H01L 29/417; H01L 21/8238; H01L 27/092

(52) U.S. Cl. CPC H01L 29/41791; H01L 21/823821; H01L 21/823871; H01L 27/0924

(57) ABSTRACT

Embodiments of the present disclosure relates to a semiconductor device structure. The structure includes a source/drain epitaxial feature disposed over a substrate, a first interlayer dielectric (ILD) disposed over the source/drain epitaxial feature, a second ILD disposed over the first ILD. The second ILD includes a first dopant species having an atomic radius equal to or greater than silicon and a second dopant species having an atomic mass less than 15. The structure also includes a first conductive feature disposed in the second ILD, and a second conductive feature disposed over the source/drain epitaxial feature, the second conductive feature extending through the first ILD and in contact with the first conductive feature.

### CROSS-REFERENCE TO RELATED APPLICATIONS

This application claims priority to U.S. Provisional Application Ser. No. 63/422,942 filed Nov. 5, 2022, which is incorporated by reference in its entirety.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a Fin Field Effect Transistor (FinFET). FinFET devices typically include semiconductor fins with high aspect ratios and in which channel and source/drain regions are formed. A gate is formed over and along the sides of the fin structure (e.g., wrapping) utilizing the advantage of the increased surface area of the channel to produce faster, more reliable, and better-controlled semiconductor transistor devices. However, with the decreasing in scaling, the critical dimension (CD) between adjacent contact features becomes smaller. To achieve high performance of integrated circuits (ICs), the higher resistance due to the smaller CD to neighboring metal features in the bank-end-of-line (BEOL) has become a critical issue.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4 are perspective views of various stages of manufacturing a semiconductor device structure, in accordance with some embodiments.

FIGS. 5A-21A are cross-sectional side views of various stages of manufacturing the semiconductor device structure of FIG. 4 taken along cross-section A-A, in accordance with some embodiments.

FIGS. 5B-21B are cross-sectional side views of various stages of manufacturing the semiconductor device structure of FIG. 4 taken along cross-section B-B, in accordance with some embodiments.

FIGS. 22-25 illustrate cross-sectional side views of the semiconductor device structure of FIG. 4 taken along cross-section B-B, in accordance with some alternative embodiments.

FIG. 26 is an enlarged view of a portion of the semiconductor device structure of FIG. 25.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

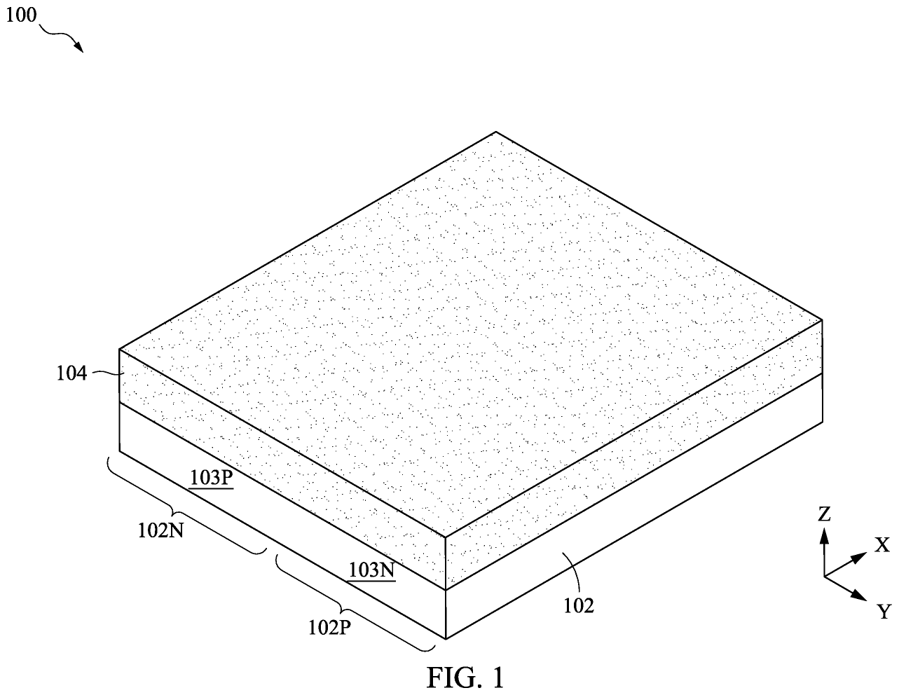

FIGS. 1-26 illustrate various stages of manufacturing a semiconductor device structure 100 in accordance with various embodiments of this disclosure. It is understood that additional operations can be provided before, during, and after processes shown by FIGS. 1-26 and some of the operations described below can be replaced or eliminated, for additional embodiments of the method. The order of the operations/processes may be interchangeable.

FIGS. 1-4 are perspective views of various stages of manufacturing a semiconductor device structure 100, in accordance with some embodiments. In FIG. 1, a first semiconductor layer 104 is formed on a substrate 102. The substrate may be a part of a chip in a wafer. In some embodiments, the substrate 102 is a bulk semiconductor substrate, such as a semiconductor wafer. For example, the substrate 102 is a silicon wafer. The substrate 102 may include silicon or another elementary semiconductor material such as germanium. In some other embodiments, the substrate 102 includes a compound semiconductor. The compound semiconductor may include gallium arsenide, silicon carbide, indium arsenide, indium phosphide, another suitable semiconductor material, or a combination thereof. In some embodiments, the substrate 102 is a semiconductor-on-insulator (SOI) substrate. The SOI substrate may be fabricated using a separation by implantation of oxygen (SIMOX) process, a wafer bonding process, another applicable method, or a combination thereof.

The substrate 102 may be doped with P-type or N-type impurities. As shown in FIG. 1, the substrate 102 has a P-type region 102P and an N-type region 102N adjacent to the P-type region 102P, and the P-type region 102P and N-type region 102N belong to a continuous substrate 102, in accordance with some embodiments. In some embodiments of the present disclosure, the P-type region 102P is used to form a PMOS device thereon, whereas the N-type region 102N is used to form an NMOS device thereon. In some embodiments, an N-well region 103N and a P-well region 103P are formed in the substrate 102, as shown in FIG. 1. For example, the N-well region 103N may be formed in the substrate 102 in the P-type region 102P, whereas the P-well region 103P may be formed in the substrate 102 in the N-type region 102N. The P-well region 103P and the N-well region 103N may be formed by any suitable technique, for example, by separate ion implantation processes in some embodiments. By using two different implantation mask layers (not shown), the P-well region 103P and the N-well region 103N can be sequentially formed in different ion implantation processes.

The first semiconductor layer 104 is deposited over the substrate 102, as shown in FIG. 1. The first semiconductor layer 104 may be made of any suitable semiconductor material, such as silicon, germanium, III-V semiconductor material, or combinations thereof. In one exemplary embodiment, the first semiconductor layer 104 is made of silicon. The first semiconductor layer 104 may be formed by an epitaxial growth process, such as metal-organic chemical vapor deposition (MOCVD), metal-organic vapor phase epitaxy (MOVPE), plasma-enhanced chemical vapor deposition (PECVD), remote plasma chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable process.

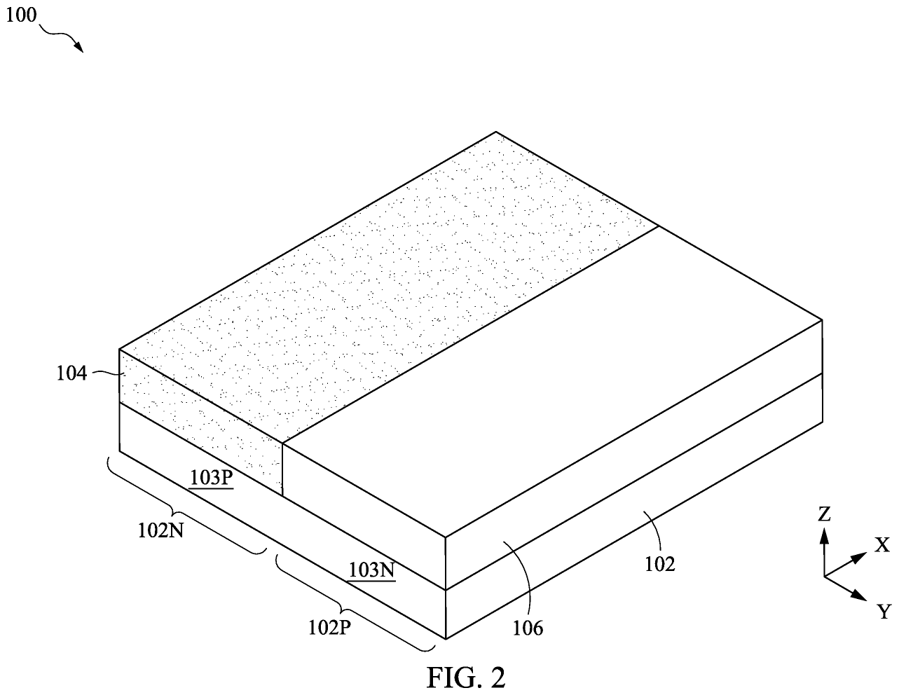

In FIG. 2, the portion of the first semiconductor layer 104 disposed over the N-well region 103N is removed, and a second semiconductor layer 106 is formed over the N-well region 103N and adjacent the portion of the first semiconductor layer 104 disposed over the P-well region 103P. A patterned mask layer (not shown) may be first formed on the portion of the first semiconductor layer 104 disposed over the P-well region 103P, and the portion of the first semiconductor layer 104 disposed over the N-well region 103N may be exposed. A removal process, such as a dry etch, wet etch, or a combination thereof, may be performed to remove the portion of the first semiconductor layer 104 disposed over the N-well region 103N, and the N-well region 103N may be exposed. The removal process does not substantially affect the mask layer (not shown) formed on the portion of the first semiconductor layer 104 disposed over the P-well region 103P, which protects the portion of the first semiconductor layer 104 disposed over the P-well region 103P. Next, the second semiconductor layer 106 is formed on the exposed N-well region 103N. The second semiconductor layer 106 may be made of any suitable semiconductor material, such as silicon, germanium, III-V semiconductor material, or combinations thereof. In one exemplary embodiment, the second semiconductor layer 106 is made of silicon germanium. The second semiconductor layer 106 may be formed by the same process as the first semiconductor layer 104. For example, the second semiconductor layer 106 may be formed on the exposed N-well region 103N by an epitaxial growth process, which does not form the second semiconductor layer 106 on the mask layer (not shown) disposed on the first semiconductor layer 104. As a result, the first semiconductor layer 104 is disposed over the P-well region 103P in the N-type region 102N, and the second semiconductor layer 106 is disposed over the N-well region 103N in the P-type region 102P.

Portions of the first semiconductor layer 104 may serve as channels in the subsequently formed NMOS device in the N-type region 102N. Portions of the second semiconductor layer 106 may serve as channels in the subsequently formed PMOS device in the P-type region 102P. In some embodiments, the NMOS device and the PMOS device are FinFETs. While embodiments described in this disclosure are described in the context of FinFETs, implementations of some aspects of the present disclosure may be used in other processes and/or in other devices, such as planar FETs, dual-gate FETs, tri-gate FETS, nanosheet channel FETs, forksheet FETs, Horizontal Gate All Around (HGAA) FETs, Vertical Gate All Around (VGAA) FETs, complementary FETs, negative-capacitance FETs, and other suitable devices.

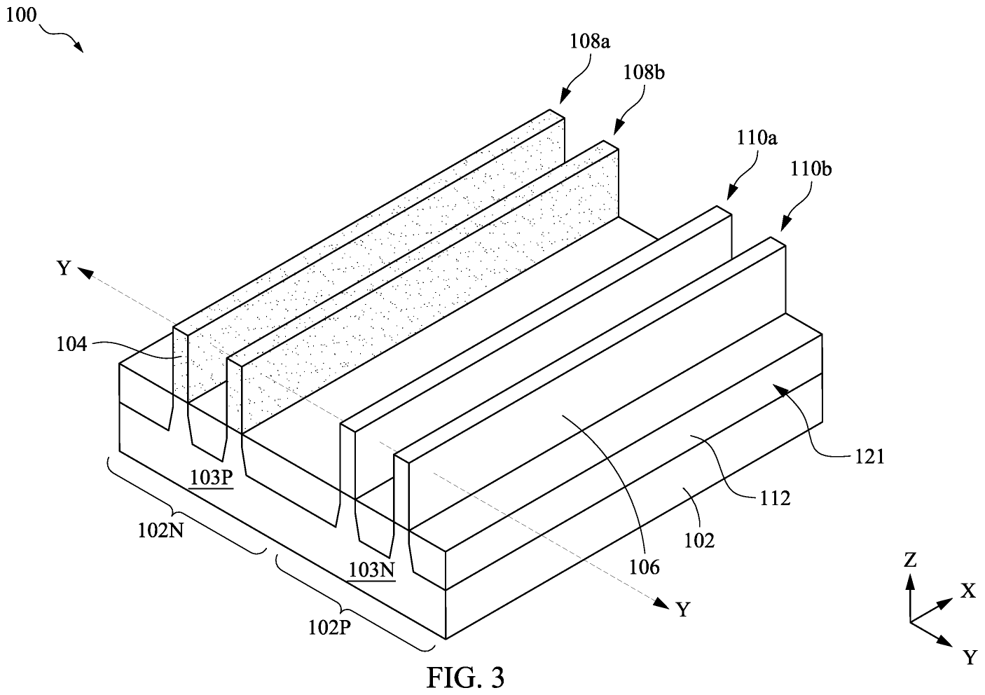

In FIG. 3, a plurality of fins 108a, 108b, 10a, 10b are formed from the first and second semiconductor layers 104, 106, respectively, and STI regions 121 are formed. The fins 108a, 108b, 110a, 10b may be patterned by any suitable method. For example, the fins 108a, 108b, 110a, 110b may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer (not shown) is formed over a substrate and patterned using a photolithography process. Spacers (not shown) are formed alongside the patterned sacrificial layer using a self-aligned process. The sacrificial layer is then removed, and the remaining spacers may then be used to pattern the substrate and form the fins.

The fins 108a, 108b may each include the first semiconductor layer 104, and a portion of the first semiconductor layer 104 may serve as an NMOS channel. Each fin 108a, 108b may also include the P-well region 103P. Likewise, the fins 110a, 110b may each include the second semiconductor layer 106, and a portion of the second semiconductor layer 106 may serve as a PMOS channel. Each fin 110a, 110b may also include the N-well region 103N. A mask (not shown) may be formed on the first and second semiconductor layers 104, 106, and may remain on the fins 108a-b and 110a-b.

Once the fins 108a-b, 110a-b are formed, an insulating material 112 is formed between adjacent fins 108a-b, 110a-b. The insulating material 112 may be first formed between adjacent fins 108a-b, 110a-b and over the fins 108a-b, 110a-b, so the fins 108a-b, 110a-b are embedded in the insulating material 112. A planarization process, such as a chemical-mechanical polishing (CMP) process may be performed to expose the top of the fins 108a-b, 10a-b. In some embodiments, the planarization process exposes the top of the mask (not shown) disposed on the fins 108a-b and 110a-b. The insulating material 112 are then recessed by removing a portion of the insulating material 112 located on both sides of each fin 108a-b, 110a-b. The insulating material 112 may be recessed by any suitable removal process, such as dry etch or wet etch that selectively removes the insulating material 112 but does not substantially affect the semiconductor materials of the fins 108a-b, 110a-b. The insulating material 112 may include an oxygen-containing material, such as silicon oxide, carbon or nitrogen doped oxide, or fluorine-doped silicate glass (FSG); a nitrogen-containing material, such as silicon nitride, silicon oxynitride (SiON), SiOCN, SiCN; a low-K dielectric material (e.g., a material having a K value lower than that of silicon dioxide); or any suitable dielectric material. The insulating material 112 may be formed by any suitable method, such as low-pressure chemical vapor deposition (LPCVD), plasma enhanced CVD (PECVD) or flowable CVD (FCVD). The insulating material 112 may be shallow trench isolation (STI) region, and is referred to as STI region 121 in this disclosure.

In some alternative embodiments, instead of forming first and second semiconductor layers 104, 106 over the substrate 102, the fins 108a-b, 110a-b may be formed by first forming isolation regions (e.g., STI regions 121) on a bulk substrate (e.g., substrate 102). The formation of the STI regions may include etching the bulk substrate to form trenches, and filling the trenches with a dielectric material to form the STI regions. The portions of the substrate between neighboring STI regions form the fins. The top surfaces of the fins and the top surfaces of the STI regions may be substantially level with each other by a CMP process. After the STI regions are formed, at least top portions of, or substantially entireties of, the fins are removed. Accordingly, recesses are formed between STI regions. The bottom surfaces of the STI regions may be level with, higher, or lower than the bottom surfaces of the STI regions. An epitaxy is then performed to separately grow first and second semiconductor layers (e.g., first and second semiconductor layers 104, 106) in the recesses created as a result of removal of the portions of the fins, thereby forming fins (e.g., fins 108a-b, 110a-b). A CMP is then performed until the top surfaces of the fins and the top surfaces of the STI regions are substantially co-planar. In some embodiments, after the epitaxy and the CMP, an implantation process is performed to define well regions (e.g., P-well region 103P and N-well region 103N) in the substrate. Alternatively, the fins are in-situ doped with impurities (e.g., dopants having P-type or N-type conductivity) during the epitaxy. Thereafter, the STI regions are recessed so that fins of first and second semiconductor layers (e.g., fins 108a-b, 110a-b) are extending upwardly over the STI regions from the substrate, in a similar fashion as shown in FIG. 3.

In some alternative embodiments, one of the fins 108a-b (e.g., fin 108a) in the N-type region 102N is formed of the second semiconductor layer 106, and the other fin 108b in the N-type region 102N is formed of the first semiconductor layer 104. In such cases, the subsequent epitaxial S/D features 152 formed on the fins 108a and 108b in the N-type region 102N may be Si or SiP; the subsequent epitaxial S/D features 152 formed on the fins 110a and 110b in the P-type region 102P may be SiGe. In some alternative embodiments, the fins 108a-b and 110a-b are formed directly from a bulk substrate (e.g., substrate 102), which may be doped with P-type or N-type impurities to form well regions (e.g., P-well region 103P and N-well region 103N). In such cases, the fins are formed of the same material as the substrate 102. In one exemplary embodiment, the fins and the substrate 102 are formed of silicon.

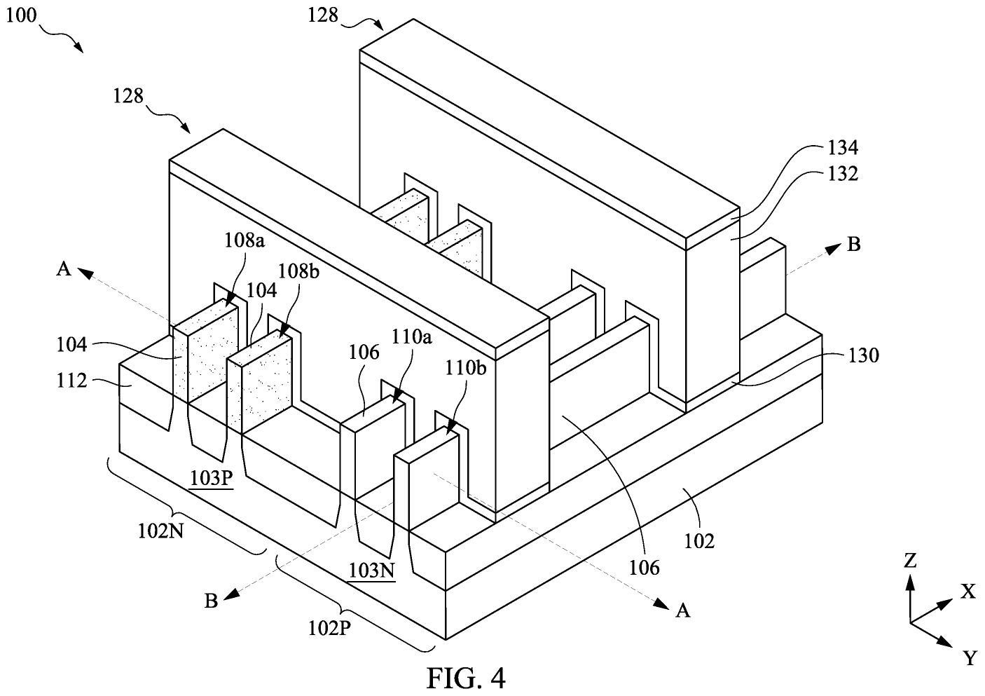

In FIG. 4, one or more sacrificial gate stacks 128 are formed on a portion of the fins 108a-b, 110a-b. Each sacrificial gate stack 128 may include a sacrificial gate dielectric layer 130, a sacrificial gate electrode layer 132, and a mask structure 134. The sacrificial gate dielectric layer 130 may include one or more layers of dielectric material, such as SiO₂, SiN, a high-K dielectric material, and/or other suitable dielectric material. In some embodiments, the sacrificial gate dielectric layer 130 may be deposited by a CVD process, an ALD process, a PVD process, or other suitable process. The sacrificial gate electrode layer 132 may include polycrystalline silicon (polysilicon). The mask structure 134 may include an oxygen-containing layer and a nitrogen-containing layer. In some embodiments, the sacrificial gate electrode layer 132 and the mask structure 134 are formed by various processes such as layer deposition, for example, CVD (including both LPCVD and PECVD), PVD, ALD, thermal oxidation, e-beam evaporation, or other suitable deposition techniques, or combinations thereof.

The sacrificial gate stacks 128 may be formed by first depositing blanket layers of the sacrificial gate dielectric layer 130, the sacrificial gate electrode layer 132, and the mask structure 134, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch, wet etch, other etch methods, and/or combinations thereof. By patterning the sacrificial gate stacks 128, the fins 108a-b, 110a-b are partially exposed on opposite sides of the sacrificial gate stacks 128. While two sacrificial gate stacks 128 are shown in FIG. 4, it can be appreciated that they are for illustrative purpose only and any number of the sacrificial gate stacks 128 may be formed.

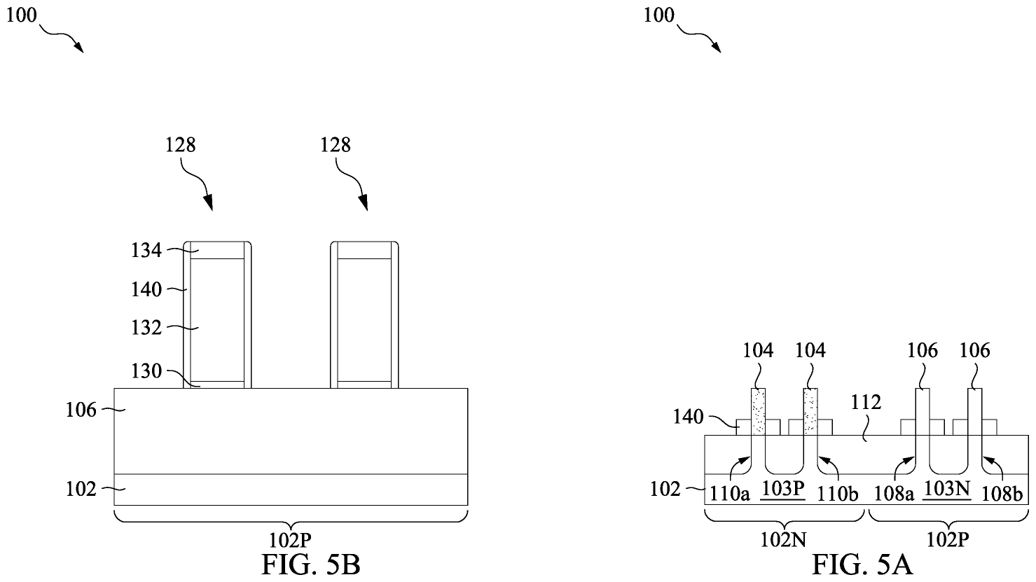

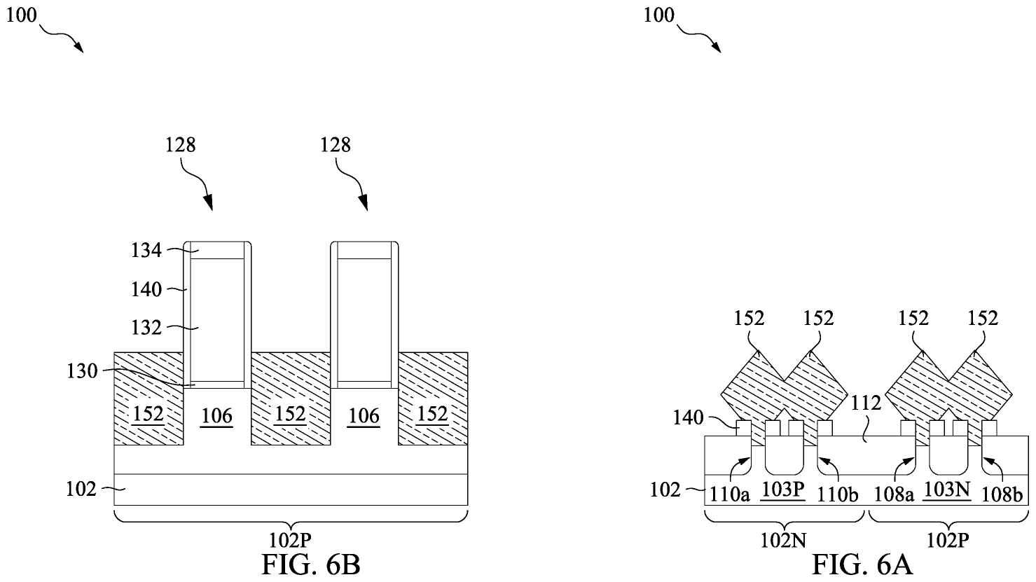

FIGS. 5A-22A are cross-sectional side views of various stages of manufacturing the semiconductor device structure 100 of FIG. 4 taken along cross-section A-A, in accordance with some embodiments. FIGS. 5B-22B are cross-sectional side views of various stages of manufacturing the semiconductor device structure 100 of FIG. 4 taken along cross-section B-B, in accordance with some embodiments. Cross-section B-B is in a plane of the fin 110b along the X direction. Cross-section A-A is in a plane perpendicular to cross-section B-B and is in the epitaxial S/D features 152 (FIG. 6A) along the Y-direction.

In FIGS. 5A-5B, a gate spacer 140 is formed on the sacrificial gate structures 128 and the exposed portions of the first and second semiconductor layers 104, 106. The gate spacer 140 may be conformally deposited on the exposed surfaces of the semiconductor device structure 100. The conformal gate spacer 140 may be formed by ALD or any suitable processes. An anisotropic etch is then performed on the gate spacer 140 using, for example, reactive ion etching (RIE). During the anisotropic etch process, most of the gate spacer 140 is removed from horizontal surfaces, such as tops of the sacrificial gate structures 128 and tops of the fins 108a-b, 110a-b, leaving the gate spacer 140 on the vertical surfaces, such as on opposite sidewalls of the sacrificial gate structures 128. The gate spacers 140 may partially remain on opposite sidewalls of the fins 108a-b, 110a-b, as shown in FIG. 5A. In some embodiments, the gate spacers 140 formed on the source/drain regions of the fins 108a-b, 110a-b are fully removed.

The gate spacer 140 may be made of a dielectric material such as silicon oxide (SiO₂), silicon nitride (Si₃N₄), silicon carbide (SiC), silicon oxynitride (SiON), silicon carbon-nitride (SiCN), silicon oxycarbide (SiOC), silicon oxycarbonitride (SiOCN), air gap, and/or any combinations thereof. In some embodiments, the gate spacer 140 include one or more layers of the dielectric material discussed herein.

In FIGS. 6A-6B, the first and second semiconductor layers 104, 106 of the fins 108a-b, 110a-b not covered by the sacrificial gate structures 128 and the gate spacers 140 are recessed, and source/drain (S/D) epitaxial features 152 are formed. For N-channel FETs, the epitaxial S/D features 152 may include one or more layers of Si, SiP, SiC, SiCP, or a group III-V material (InP, GaAs, AlAs, InAs, InAlAs, InGaAs). In some embodiments, the epitaxial S/D features 152 may be doped with N-type dopants, such as phosphorus (P), arsenic (As), etc, for N-type devices. For P-channel FETs, the epitaxial S/D features 152 may include one or more layers of Si, SiGe, SiGeB, Ge, or a group III-V material (InSb, GaSb, InGaSb). In some embodiments, the epitaxial S/D features 152 may be doped with P-type dopants, such as boron (B). The epitaxial S/D features 152 may grow both vertically and horizontally to form facets, which may correspond to crystalline planes of the material used for the substrate 102. The epitaxial S/D features 152 may be formed by an epitaxial growth method using CVD, ALD or MBE.

In some embodiments, the portions of the first semiconductor layer 104 on both sides of each sacrificial gate structure 128 are completely removed, and the epitaxial S/D features 152 are formed on the P-well region 103P of the fins 108a-b. The epitaxial S/D features 152 may grow both vertically and horizontally to form facets, which may correspond to crystalline planes of the material used for the substrate 102. In some embodiments, the epitaxial S/D features 152 of the fins 108a-108b and 110a-110b are merged, as shown in FIG. 6A. The epitaxial S/D features 152 may each have a top surface at a level higher than a top surface of the first semiconductor layer 104, as shown in FIG. 6B.

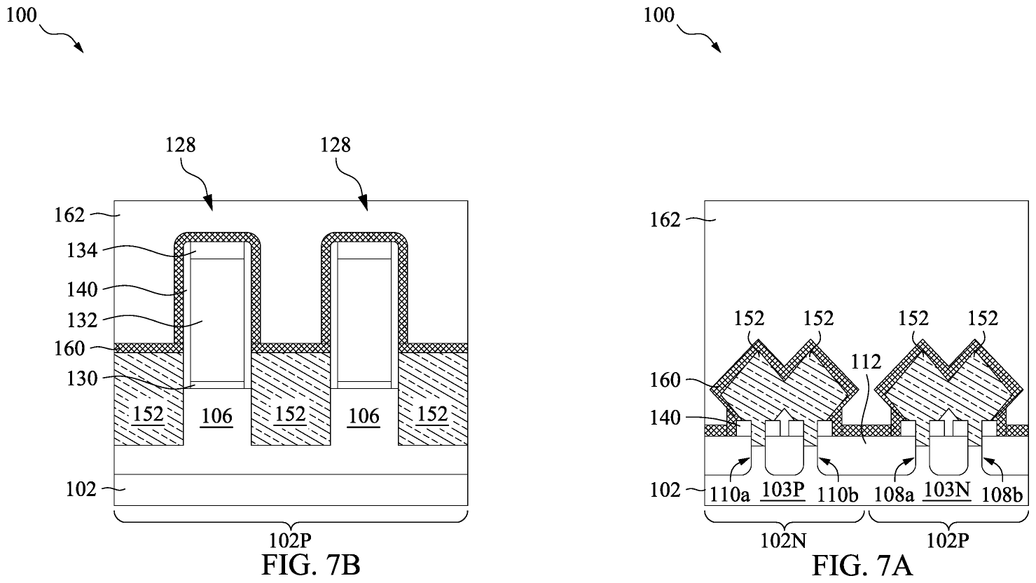

In FIGS. 7A-7B, a contact etch stop layer (CESL) 160 is conformally formed on the exposed surfaces of the semiconductor device structure 100. The CESL 160 covers the sidewalls of the sacrificial gate structures 128, the insulating material 112, and the epitaxial S/D features 152. The CESL 160 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (TLD) 162 is formed on the CESL 160. The materials for the first ILD 162 may include compounds comprising Si, O, C, and/or H, such as tetraethylorthosilicate (TEOS) oxide, un-doped silicate glass, silicon oxide, or doped silicon oxide such as borophosphosilicate glass (BPSG), fused silica glass (FSG), phosphosilicate glass (PSG), boron doped silicon glass (BSG), and/or other suitable dielectric materials. The first ILD 162 may be deposited by a PECVD process or FCVD process or other suitable deposition technique. In some embodiments, after formation of the first ILD 162, the semiconductor device structure 100 may be subject to a thermal process to anneal the first ILD 162. After formation of the first ILD 162, a planarization process is performed to expose the sacrificial gate electrode layer 132. The planarization process may be any suitable process, such as a CMP process. The planarization process removes portions of the first ILD 162 and the CESL 160 disposed on the sacrificial gate structures 128. The planarization process may also remove the mask structure 134.

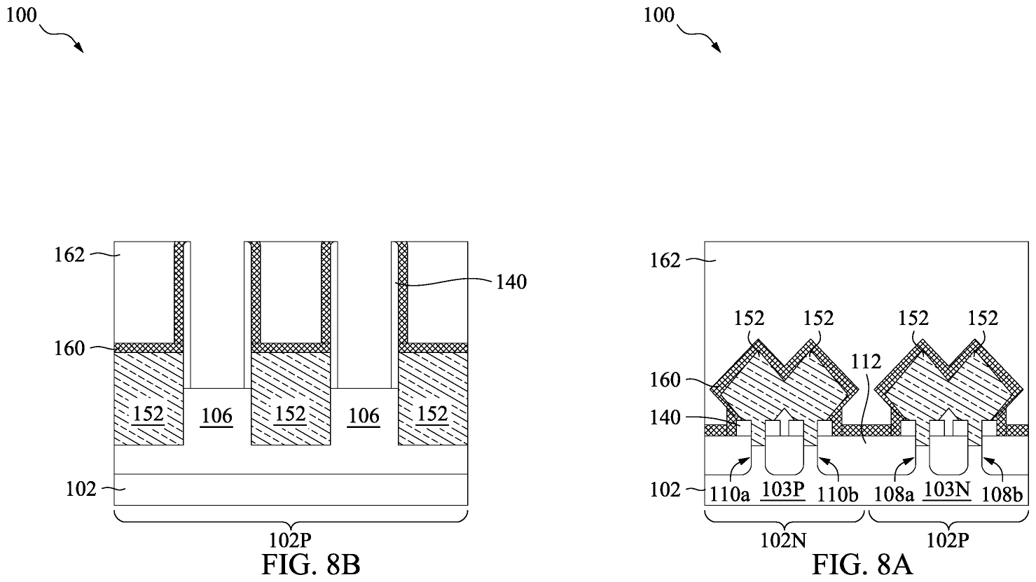

In FIGS. 8A-8B, the mask structure 134 (if not removed during previous CMP process), the sacrificial gate electrode layers 132 (FIG. 7B), and the sacrificial gate dielectric layers 130 (FIG. 7B) are removed. The sacrificial gate electrode layers 132 and the sacrificial gate dielectric layers 130 may be removed by one or more etch processes, such as dry etch process, wet etch process, or a combination thereof. The one or more etch processes selectively remove the sacrificial gate electrode layers 132 and the sacrificial gate dielectric layers 130 without substantially affects the gate spacer 140, the CESL 160, and the first ILD 162. The removal of the sacrificial gate electrode layers 132 and the sacrificial gate dielectric layers 130 exposes a top portion of the first and second semiconductor layers 104, 106 (only first semiconductor layers 104 can be seen in FIG. 8A) in the channel region.

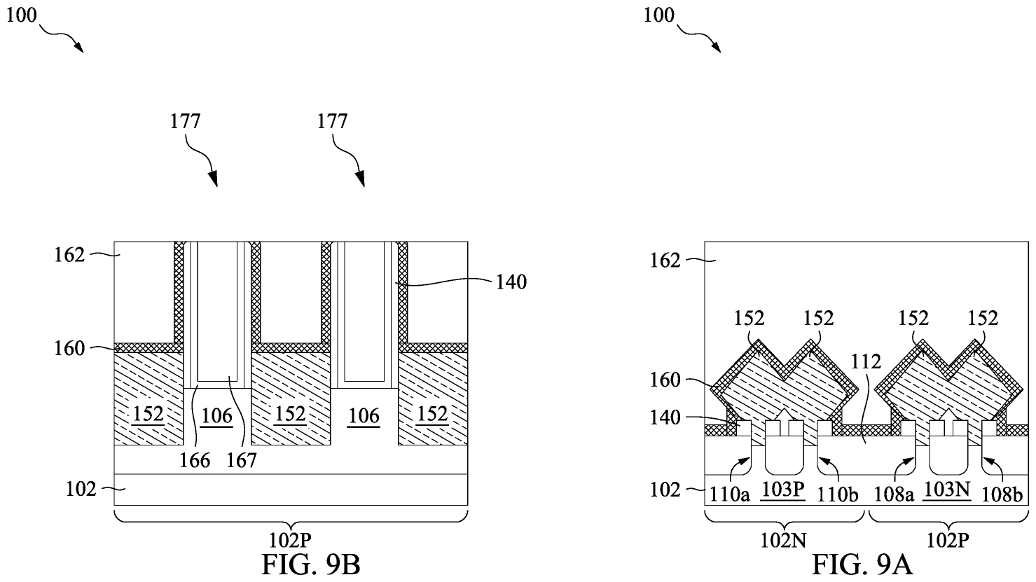

In FIGS. 9A-9B, replacement gate structures 177 are formed. The replacement gate structure 177 may include a gate dielectric layer 166 and a gate electrode layer 167 formed on the gate dielectric layer 166. The gate dielectric layer 166 may include one or more dielectric layers and may include the same material(s) as the sacrificial gate dielectric layer 130.

In some embodiments, the gate dielectric layer 166 is a high-K dielectric material such as metal oxides, metal nitrides, metal silicates, transition metal-oxides, transition metal-nitrides, transition metal-silicates, oxynitrides of metals, metal aluminates, zirconium silicate, zirconium aluminate, or any combination thereof. For example, the gate dielectric layer 166 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃), barium titanium oxide (BaTiO₃), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. In alternative embodiments, the gate dielectric layer 166 may have a multilayer structure such as one layer of silicon oxide (e.g., interfacial layer) and another layer of high-K material. In some embodiments, the gate dielectric layer 166 may be deposited by one or more ALD processes or other suitable processes.

Depending on the application and/or conductivity type of the devices in the N-type region 102N and the P-type region 102P, the gate electrode layer 167 may include one or more layers of electrically conductive material, such as polysilicon, aluminum, copper, titanium, tantalum, tungsten, cobalt, molybdenum, tantalum nitride, nickel silicide, cobalt silicide, TiN, WN, AlTi, AlTiO, AlTiC, AlTiN, TaCN, TaC, TaSiN, metal alloys, other suitable materials, and/or any combinations thereof. For devices in the N-type region 102N, the gate electrode layer 167 may be AlTiO, AlTiC, or a combination thereof. For devices in the P-type region 102P, the gate electrode layer 167 may be AlTiO, AlTiC, AlTiN, or a combination thereof. The gate electrode layers 167 may be formed by PVD, CVD, ALD, electro-plating, or other suitable method.

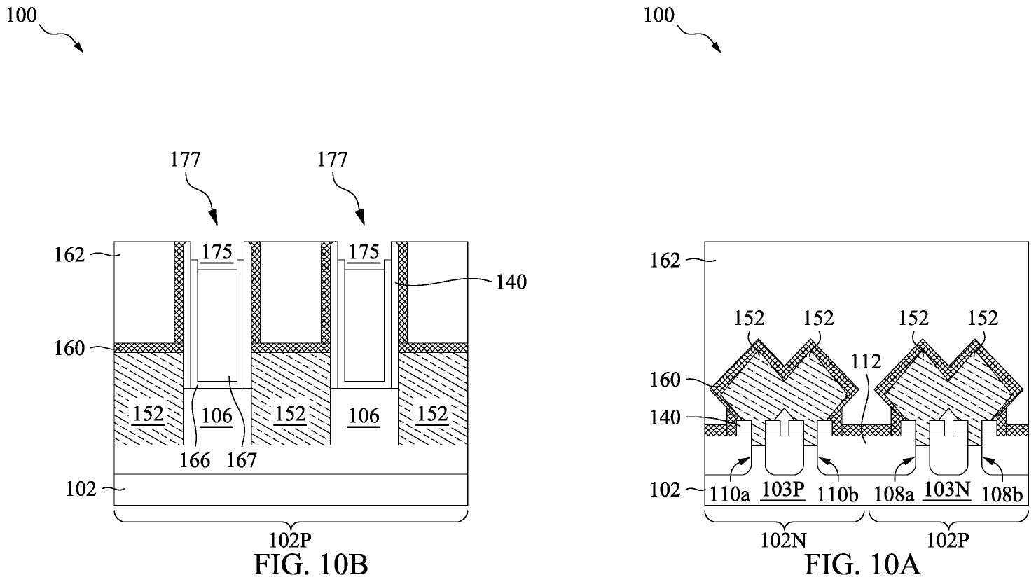

In FIGS. 10A-10B, an optional metal gate etching back (MGEB) process is performed to remove portions of the gate dielectric layer 166 and the gate electrode layer 167. Recesses 175 are formed in the region between neighboring gate spacers 140 as a result of the removal of the portions of the gate dielectric layer 166 and the gate electrode layer 167. The recesses 175 are defined by the exposed sidewalls of the gate spacers 140 and the recessed top surfaces of the gate electrode layers 167 and the gate dielectric layers 166, respectively. The recesses 175 allow for subsequent first dielectric cap layer 141 (FIG. 111B) to be formed therein and protect the replacement gate structures 177. The MGEB process may include one or more etching processes, which may be dry etching, wet etching, atomic layer etching (ALE), plasma etching, any suitable etching back, or a combination thereof. The one or more etching processes performed in the MGEB process are selective to materials of the replacement gate structures 177 with respect to the gate spacers 140 and the first ILD 162 so that the top surfaces of the gate electrode layers 167 and the gate dielectric layers 166, respectively, are at a level lower than top surfaces of the gate spacers 140 and the first ILD 162.

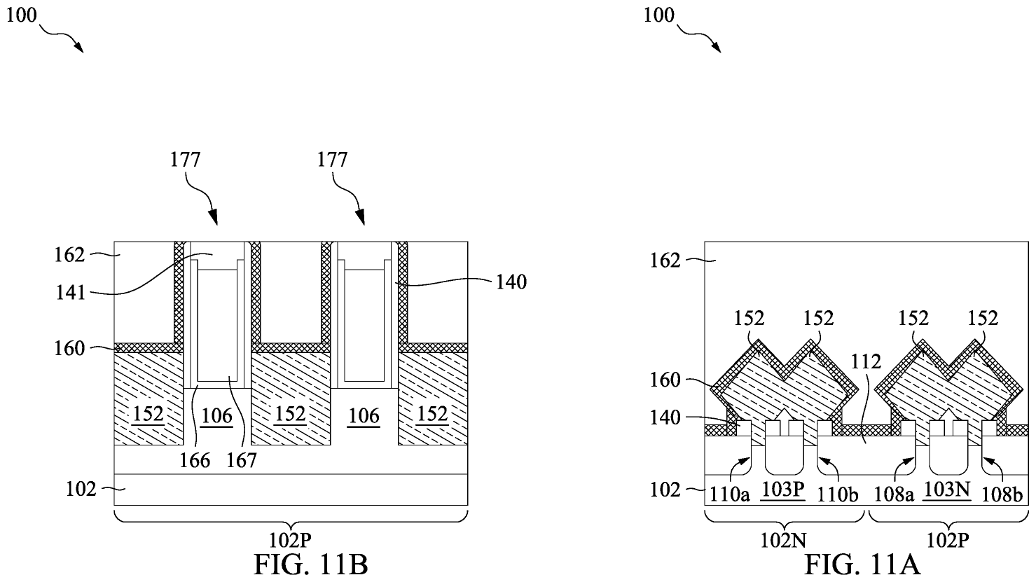

In FIGS. 11A-11B, a dielectric cap layer 141 is formed in the recesses 175 (FIG. 10B), over the replacement gate structures 177. The dielectric cap layer 141 fills in the recesses 175 and over the first ILD 162 to a pre-determined height using a deposition process, such as CVD, PECVD, or FCVD or any suitable deposition technique. A CMP process is then performed to remove excess deposition of the dielectric cap layer 141 outside the recesses 175 until the top surface of the first ILD 162 is exposed. The top surfaces of the first ILD 162, the CESL 160, the dielectric cap layer 141, and the gate spacers 140 are substantially coplanar. The dielectric cap layer 141 defines self-aligned contact (SAC) regions and thus serve as an etch stop layer during subsequent trench and via patterning for metal contacts. The dielectric cap layer 141 can be formed of any dielectric material that has different etch selectivity than the gate spacers 140, the CESL 160, and the first ILD 162. In some embodiments, the dielectric cap layer 141 may include or be formed of an oxygen-containing material, a nitrogen-containing material, or a silicon-containing material. Exemplary materials for the dielectric cap layer 141 may include, but are not limited to, SiO, HfSi, SiOC, AlO, ZrSi, AlON, ZrO, HfO, TiO, ZrAlO, ZnO, TaO, LaO, TaCN, SiN, SiOCN, Si, SiOCN, ZrN, SiCN, or any combinations thereof.

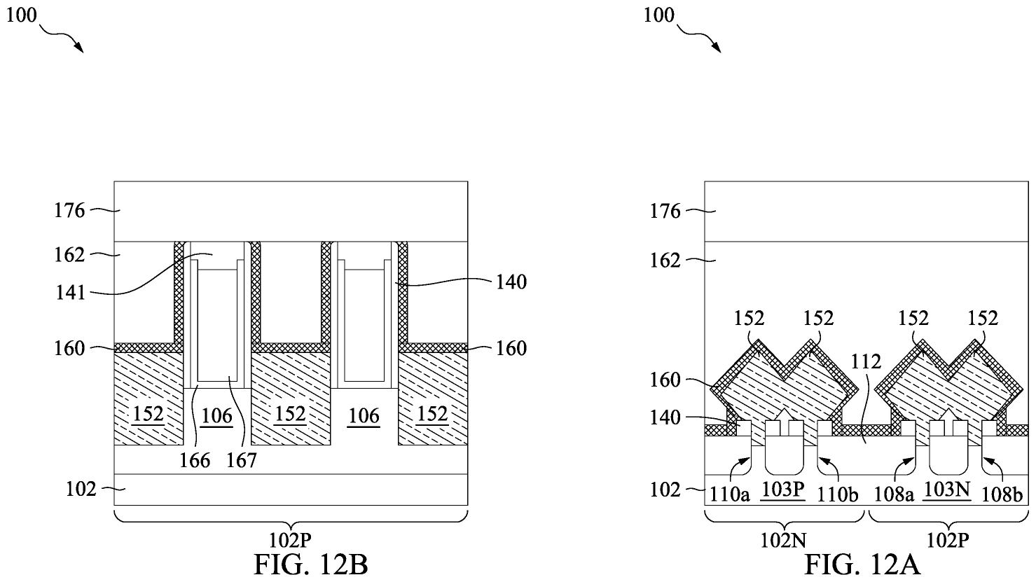

In FIGS. 12A-12B, a second ILD 176 is formed over the semiconductor device structure 100. The second ILD 176 may include the same material as the first ILD 162 and be deposited using the same fashion as the first ILD 162, as discussed above with respect to FIGS. 7A and 7B.

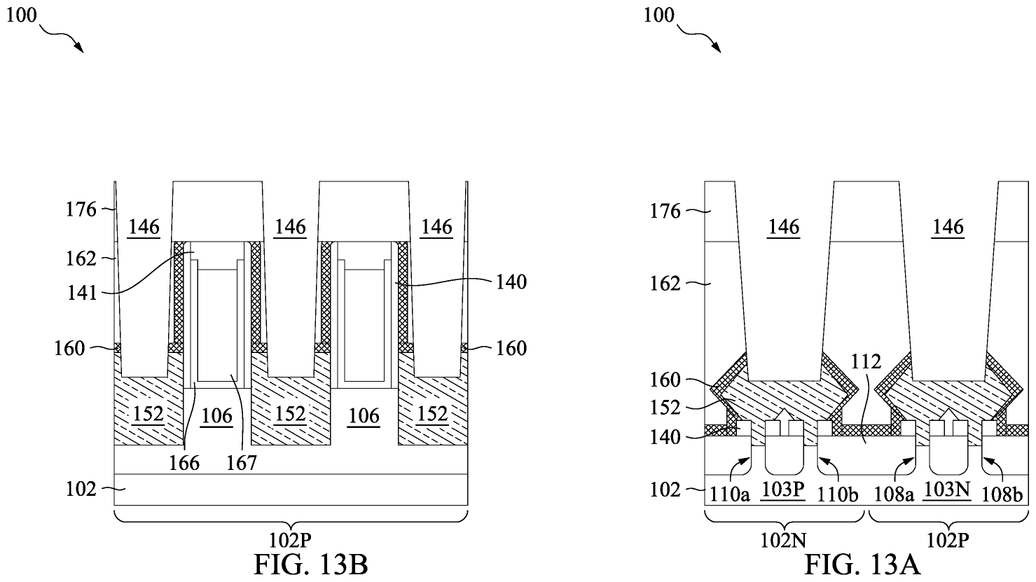

In FIGS. 13A-13B, portions of the second ILD 176, the first ILD 162, and the CESL 160 disposed on both sides of the replacement gate structures 177 are removed. The removal of the portions of the second ILD 176, the first ILD 162, and the CESL 160 forms a contact opening 146 exposing the epitaxial S/D features 152. In some embodiments, an upper portion of the exposed epitaxial S/D features 152 is also removed. An etch process, such as a dry etch, a wet etch, or a combination thereof, may be used to form the contact openings 146. The etchants used by the etch process remove the first and second ILD 162, 176, the CESL 160, and optionally the epitaxial S/D features 152.

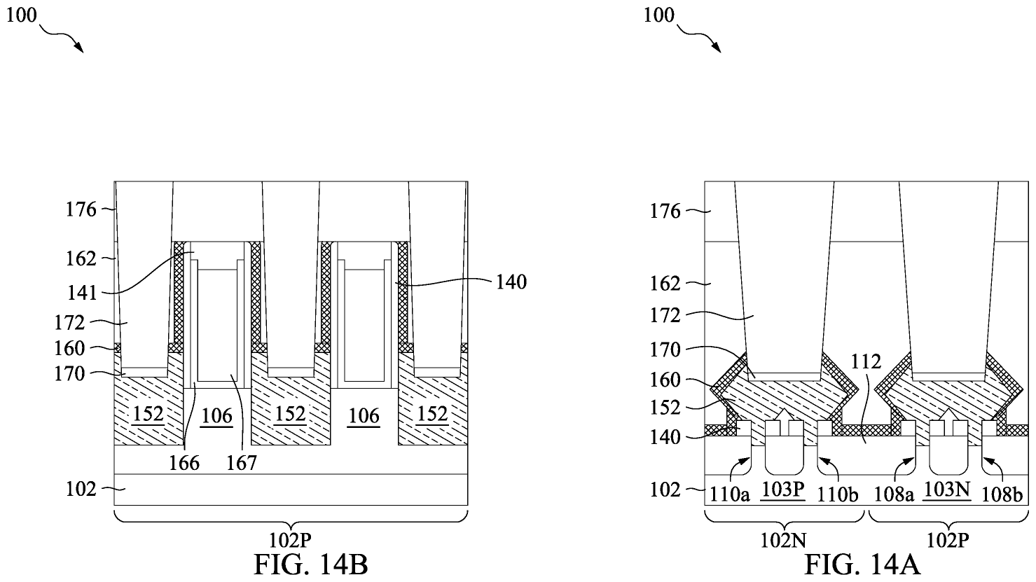

In FIGS. 14A-14B, conductive features 172 are formed over the epitaxial S/D features 152 in the contact openings 146. The conductive features 172 serve as S/D contacts. The conductive features 172 may include an electrically conductive material, such as one or more of Ru, Mo, Co, Ni. W, Ti, Ta, Cu, Al, TiN and TaN. The conductive feature 172 may be formed by any suitable process, such as PVD, CVD, ALD, electrochemical plating, or other suitable method. A silicide layer 170 may be formed between the S/D epitaxial feature 152 and the conductive feature 172. The silicide layer 170 conductively couples the epitaxial S/D features 152 to the conductive feature 172. The silicide layer 170 is a metal or metal alloy silicide, and the metal may include a noble metal, a refractory metal, a rare earth metal, alloys thereof, or combinations thereof. Once the conductive features 172 are formed, a planarization process, such as CMP, is performed on the semiconductor device structure 100 until the top surface of the second ILD 176 is exposed.

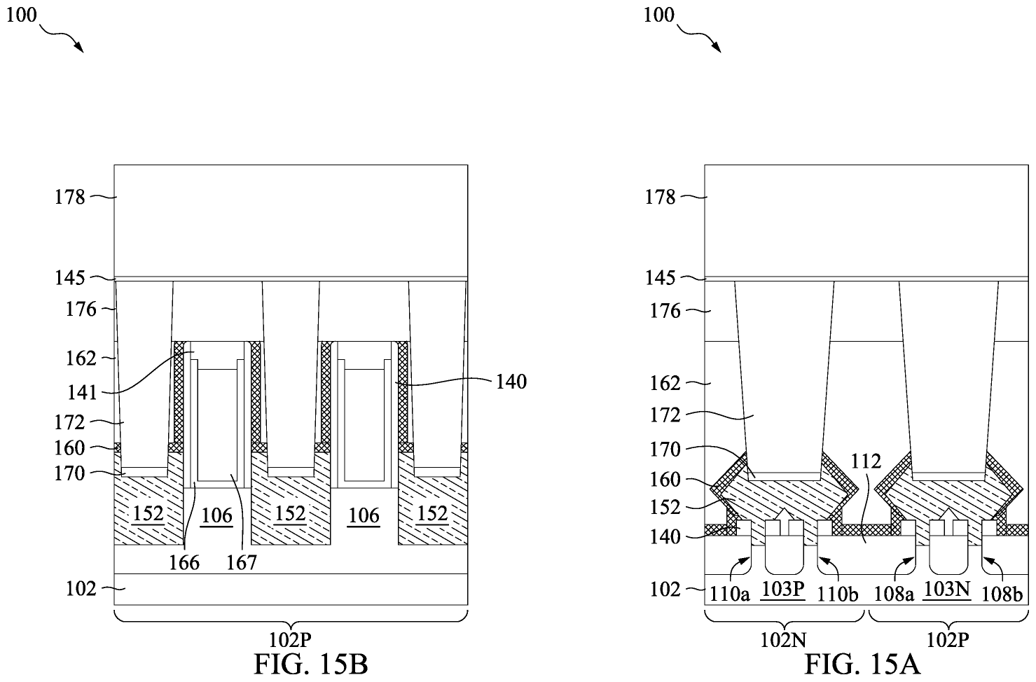

In FIGS. 15A-15B, an etch stop layer 145 and a third ILD 178 are sequentially formed over the semiconductor device structure 100. The etch stop layer 145 may be silicon nitride, silicon carbide, silicon oxycarbide (SiOC), silicon oxycarbonitride (SiOCN), silicon oxide, low-k dielectrics such as carbon doped oxides, extremely low-k dielectrics such as porous carbon doped silicon dioxide, the like, or a combination thereof, and deposited by CVD, PVD, ALD, a spin-on-dielectric process, the like, or a combination thereof. In one embodiment, the etch stop layer 145 is silicon nitride. The third ILD 178 may include the same material as the first ILD 162 and be deposited using the same fashion as the first ILD 162, as discussed above with respect to FIGS. 7A and 7B. In some embodiments, the etch stop layer 145 may have a thickness in a range of about 100 Angstroms to about 300 Angstroms, and the third ILD 178 may have a thickness in a range of about 200 Angstroms to about 700 Angstroms.

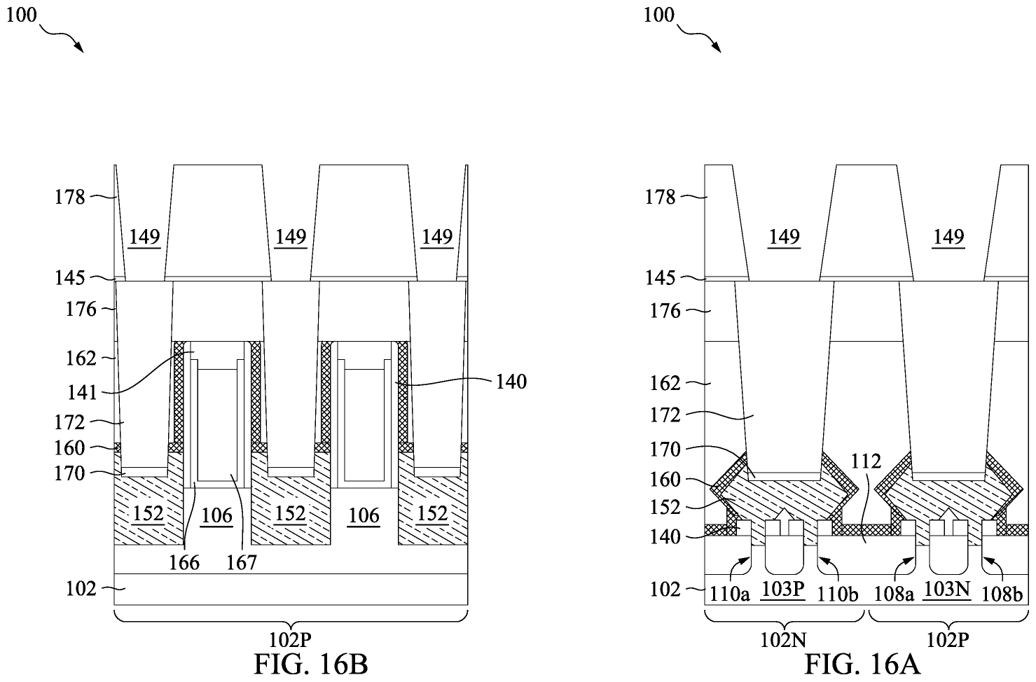

In FIGS. 16A-16B, portions of the third ILD 178 and the etch stop layer 145 disposed over the conductive features 172 are removed. The removal of the portions of the third ILD 178 and the etch stop layer 145 forms via contact openings 149 exposing the conductive features 172. A patterned layer (not shown) may be first formed on portions the third ILD 178. The patterned layer has openings at locations aligned with the epitaxial S/D features 152. The removal of the portions of the third ILD 178 and the etch stop layer 145 may be performed, using the patterned layer as a mask, by one or more etch processes, such as a wet etch, dry etch, or a combination thereof. In one embodiment, the portions of the third ILD 178 and the etch stop layer 145 are removed using a dry etch process, such as RIE or other suitable anisotropic etch process. In one exemplary embodiment, a dry etch process utilizing a capacitively coupled plasma (CCP) source, an inductively coupled plasma (ICP) source, or glow discharge plasma (GDP) source driven by an RF power generator or a microwave plasma source may be used. The dry etch process may use a plasma formed from a gas mixture containing one or more etchants, such as a bromide-based gas, a chlorine-based gas, a fluorine-based gas, and/or other suitable etching gas. An inert gas, such as argon (Ar), may be provided with the etchants to increase bombardment effect and thus, enhanced etch rates of the third ILD 178 and the etch stop layer 145. Upon formation of the via contact openings 149, the patterned layer may be removed using any suitable process, such as an ash process.

The sidewalls of the via contact openings 149 and the contact openings 146 (FIG. 13B) may be vertical or slanted. In some embodiments, the via contact openings 149 and the contact opening 146 have a sidewall profile in which the dimension at the top is greater than the dimension at the bottom of the via contact openings 149 and the contact openings 146. The via contact openings 149 and the contact openings 146 may be a round-shaped and/or oval-shaped opening when viewing from top.

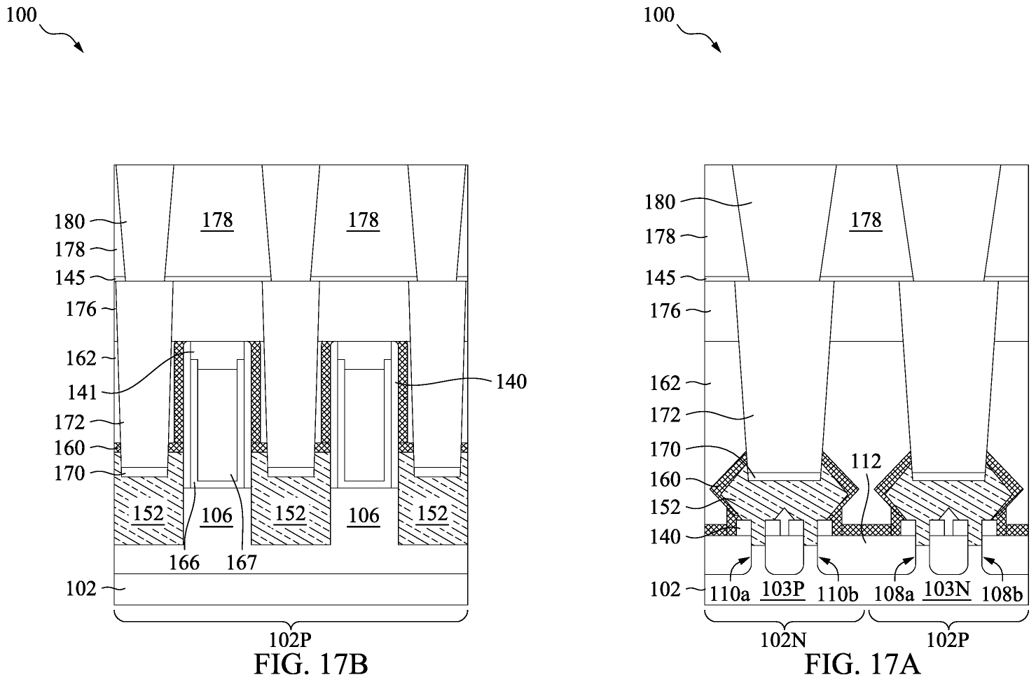

In FIGS. 17A-17B, conductive features 180 are formed in the via contact openings 149 (FIG. 16B). The conductive features 180 serve as via contacts for connecting to the epitaxial S/D features 152 through S/D contacts (e.g., conductive features 172) and connecting to the gate electrode layers 167 through gate contacts (e.g., conductive features 173). The conductive features 180 may include the same material as the conductive features 172, 173, such as one or more of Ru, Mo, Co, Ni. W, Ti, Ta, Cu, Al, TiN and TaN. The conductive feature 180 may be formed by any suitable process, such as PVD, CVD, ALD, electrochemical plating, or other suitable method. Once the conductive features 180 are formed, a planarization process, such as CMP, is performed on the semiconductor device structure 100 until the top surface of the third ILD 178 is exposed.

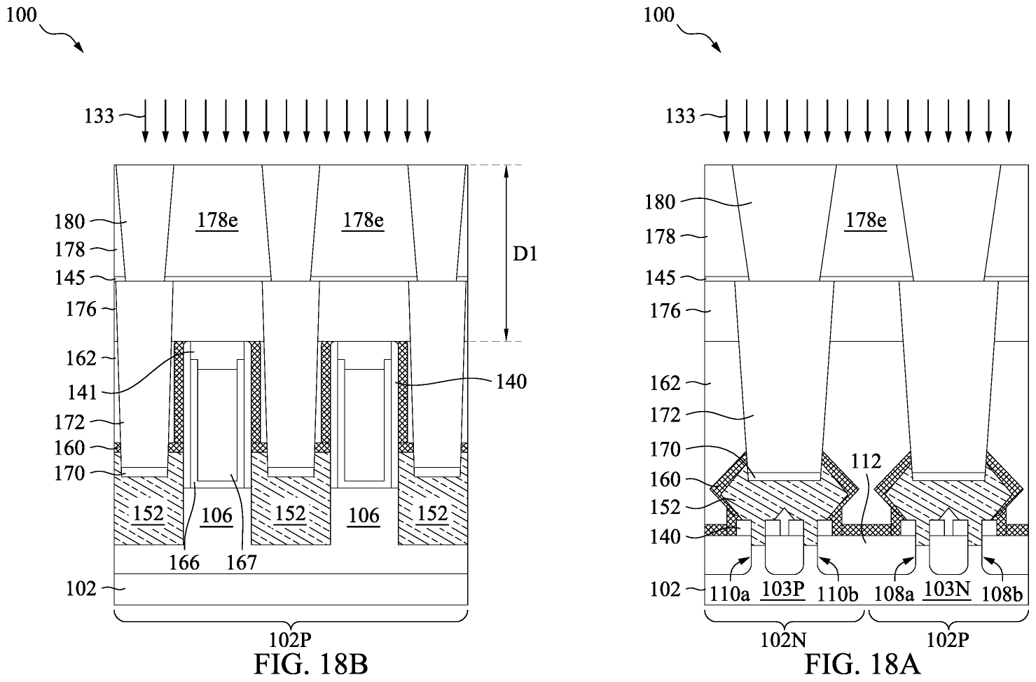

In FIGS. 18A-18B, an implantation process 133 is performed to implant the third ILD 178 and the conductive features 180 with dopants. It has been observed that the conductive features 172 (and sometimes the conductive features 180 in some cases) may not be in close contact with the sidewalls of the surrounding layers (e.g., the etch stop layer 145, the second ILD 176, and the third ILD 178) due to the process imperfection and/or nature of the materials. In such cases, an air gap may present between the conductive features 180 and the sidewalls of the third ILD 178. In some cases, the air gap may extend into regions between the conductive features 180 and the etch stop layer 145. In some cases, the air gap may further extend into regions between the conductive features 172 and the second ILD 176. During the subsequent CMP process, the air gaps may become a leakage path through which CMP slurries, polishing solutions, and/or even deposited material may seep into and damage the underlying epitaxial S/D features 152. Implanting the third ILD 178 and the conductive features 180 (and in some cases the etch stop layer 145, the second ILD 176, and the conductive features 172) with dopants can increase the volume of the implanted regions of the third ILD 178 and the conductive features 180 relative to the un-implanted regions of the third ILD 178 and the conductive features 180. Portions of the implanted regions of the third ILD 178 and the conductive features 180 may be referred to herein as expanded regions 178e. The implantation process 133 can be controlled such that the expanded regions 178e extend partially or fully across the width of the air gaps, thereby sealing the air gaps. For example, the dose, implant depth, dopant species, angle, implant energy, or other characteristics of the implantation process 133 may be controlled to control the expansion of the implanted regions. By forming expanded regions 178e to seal the air gaps in this manner, the subsequent CMP slurries, polishing solutions, and/or deposited material may be prevented from entering the air gaps and damaging the epitaxial S/D features 152.

In some embodiments, the implantation process 133 is controlled so that only a portion (e.g., surface portion) of the third ILD 178 and the conductive features 180 is implanted with dopants. In some embodiments, the implantation process 133 is controlled so that the entire third ILD 178 and the conductive features 180 are implanted with dopants. In some embodiments, the implantation process 133 is controlled so that the entire third ILD 178, the conductive features 180, and the etch stop layer 145 are implanted with dopants. In some embodiments, the implantation process 133 is controlled so that the entire third ILD 178, the conductive features 180, the etch stop layer 145, and a portion of the second ILD 176 are implanted with dopants. In some embodiments, the implantation process 133 is controlled so that the entire third ILD 178, the conductive features 180, the etch stop layer 145, and the second ILD 176 are implanted with dopants. In any cases, the dopants are implanted so that at least the third and/or second ILD 178, 176 are expanded partially or fully across the width of the air gaps, sealing most or all air gaps.

In some embodiments, the dopant species implanted by the implantation process 133 are atomic species having an atomic radius equal to or greater than silicon. For example, the dopant species may include, but are not limited to, germanium (Ge), argon (Ar), xenon (Xe), silicon (Si), arsenic (As), or the like, or a combination thereof. In one embodiment, the dopant species are Ge. In some embodiments, the implanted dopants are an atomic species having a larger atomic radius than silicon. For example, when implanted into a third ILD 178 comprising silicon, the larger size of the implanted dopants can cause the implanted regions of the third ILD 178 to increase in volume, forming expanded regions 178e. In some embodiments, the implantation process 133 includes implanting the dopants at an angle from a vertical axis that is between about 0 degree and about 60 degrees. In some cases, controlling the implantation angle can be beneficial depending on the application or device geometry. For example, the implantation process 133 may be performed at an angle to reduce straggle effects. In some embodiments, the implanted dose of dopants may be between about 10¹⁴ atoms/cm² and about 10¹⁶ atoms/cm². In some embodiments, the dopants may be implanted to a concentration of equal to or less than about 10²² cm⁻³, such as between about 10¹⁹ cm⁻³ and about 10²² cm⁻³. Increasing the implanted dose or increasing the concentration of dopants within the implanted regions can increase the expansion of the expanded regions 178e. In some embodiments, the implantation temperature is in a range of about −100 degree Celsius to about 450 degree Celsius.

While various dopant species may distribute over the implanted region in both lateral and vertical directions, the implant dosage and ion kinetic energy may be selected to achieve desired implant concentration profile in the target regions. In some embodiments, the dopant species may have an implant depth D1 in the third ILD 178, the etch stop layer 145, and the second ILD 176. The implant depth D1 indicates the depth of the gradual concentration of dopants within the third ILD 178, the etch stop layer 145, and the second ILD 176 as measured from the top of the third ILD 178. In some embodiments, the implant depth D1 is in a range of about 0 nm to about 20 nm, such as about 5 nm. In some cases, the implant depth D1 corresponds approximately to the location of the implanted regions having the traceable amount of expansion. Accordingly, by controlling the implant depth D1, the location of the expanded regions 178e can be controlled. FIGS. 18A and 18B illustrate an exemplary embodiment where the entire third ILD 178 is implanted. The implant depth D1 can be increased by increasing the implantation energy. In some embodiments, the dopants are implanted at an implantation energy between about 2 keV and about 30 keV, such as about 20 keV.

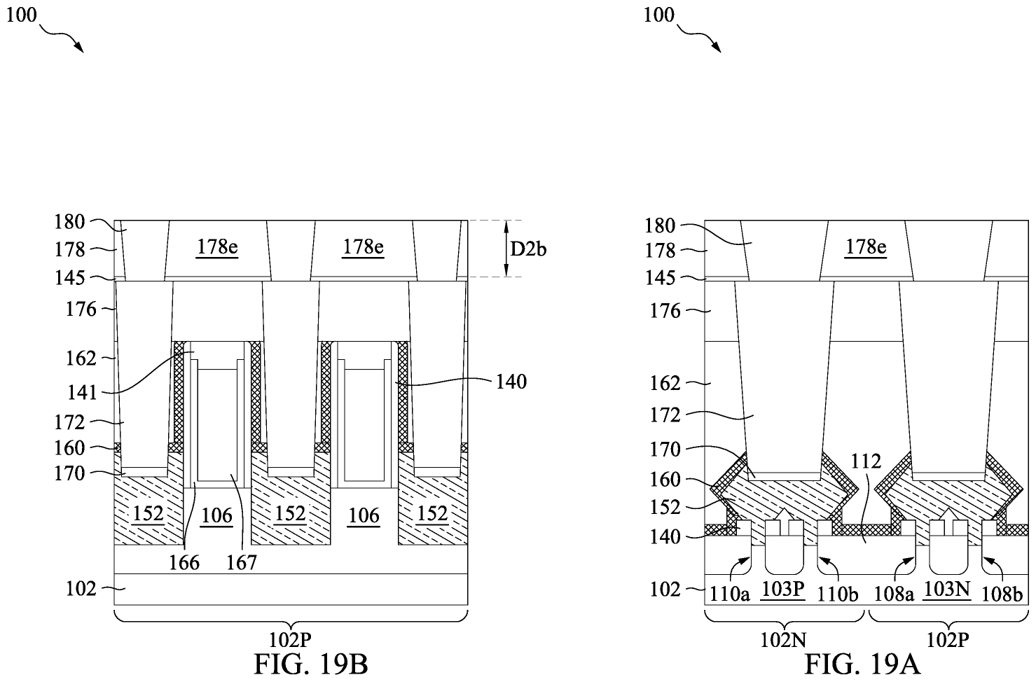

In FIGS. 19A-19B, a planarization process, such as a CMP, is performed to remove portions of the third ILD 178 and the conductive features 180. In some embodiments, the respective thickness of the third ILD 178 and the conductive features 180 is reduced by about 15% to about 35% when compared to the thickness of the third ILD 178 and the conductive features 180 before the planarization process. In one exemplary embodiment, the thickness D2a of the planarized third ILD 178 is in a range of about 6 nm to about 15 nm, for example about 10 nm.

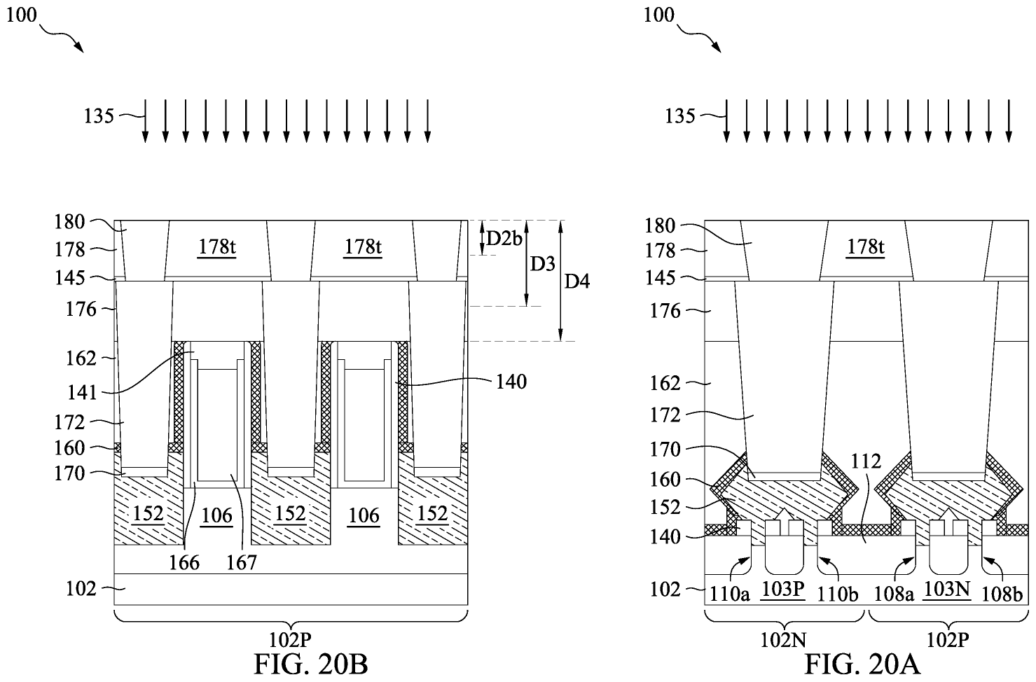

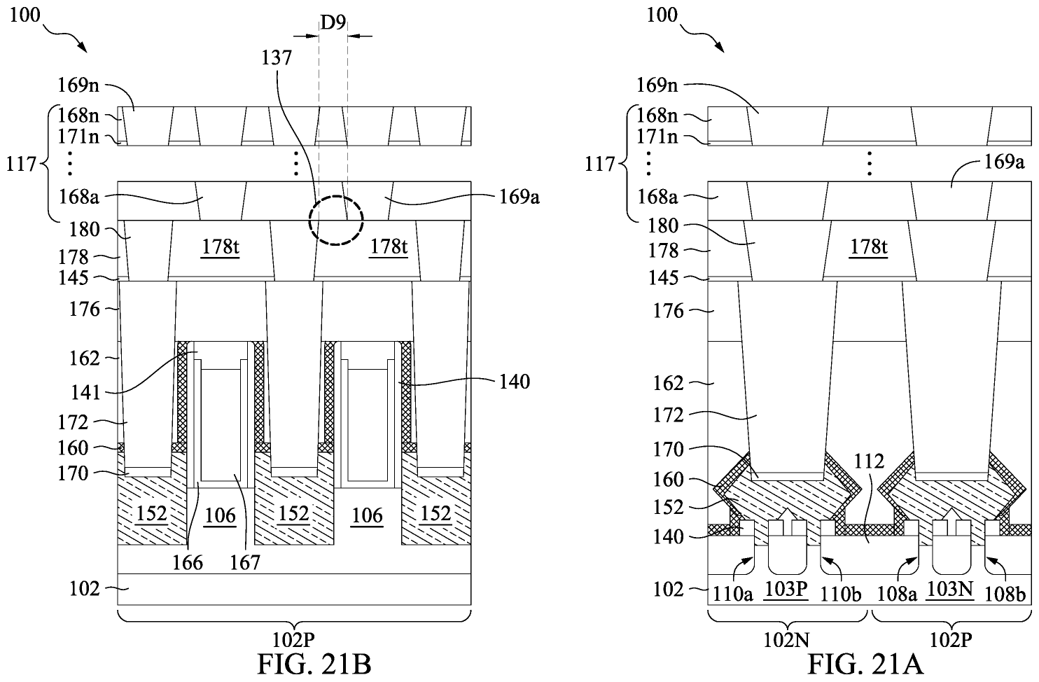

In FIGS. 20A-20B, a treatment process 135 is performed to treat the planarized third ILD 178 and the conductive features 180. It has been observed that the third ILD 178 and the conductive features 180 may also be damaged during the previous implantation process 133. Since the dopant species are chosen to have a larger atomic radius than silicon, the dopant species may deform or break crystal lattice of the third ILD 178. The dopant species may also deform the crystal lattice of the conductive features 180. In some cases, the third ILD 178 may have a great number of [H] or [OH] ions in the third ILD 178 that is formed as a result of the implantation process 133. The depth of the [H] or [OH] ions may vary depending on the implant depth D1 (FIG. 18A). In addition, when the number of [OH] ions in the damaged third ILD 178 increases, for example, a leakage current may be formed between the conductive features 180 and the subsequent contact metals (e.g., conductive features 169a in FIG. 21B). Accordingly, the chance of forming electrical shorts is increased. The treatment process 135 serves as a repairing process to recover material properties of the third ILD 178. In some cases, the treatment process 135 also reduces the degree of expansion of at least the third ILD 178. In addition, it has been observed that the [OH] ions in the treated third ILD 178 can be reduced from about 30% to about 0% when compared to the third ILD 178 without the treatment process. The reduced [OH] ions in the third ILD 178 minimizes the leakage current. Likewise, the [H] ions in the treated third ILD 178 can also be reduced from above 7% and to about 3% or below when compared to the third ILD 178 without the treatment process. Therefore, the treatment process 135 can reduce [OH] and [H] ions in the damaged third ILD 178 and result in lower leakage current.

The treatment process 135 may be an implantation process, a plasma treatment process, or a radical treatment process. In some embodiments, the dopant species, plasma species, or neutral radical species used by the implantation process, a plasma treatment process, or a radical treatment process may include helium (He). In some embodiments, the dopant species, plasma species, or neutral radical species used by the implantation process, a plasma treatment process, or a radical treatment process, plasma species are those having an atomic mass less than 15, such as hydrogen (H), lithium (Li), beryllium (Be), boron (B), carbon (C), nitrogen (N), or a combination thereof.

In some embodiments, the treatment process 135 is an implantation process. In such cases, the implantation process may be a zero-degree tilt implantation process or an angled (e.g., about 2 degrees to about 60 degrees) implantation process performed in a temperature range of about −100 degrees Celsius to about 500 degrees Celsius. While various dopant species may distribute over the implanted region in both lateral and vertical directions, the implant dosage and ion kinetic energy may be selected to achieve desired implant concentration profile in the target regions. The dopant species may be implanted at a kinetic energy in a range of about 0.3 KeV to about 50 KeV, such as about 0.5 KeV to about 10 KeV, and an implant dosage of each group of ion species may be in a range of about 5E10¹³ atoms/cm² to about 5E10¹⁶ atoms/cm², which may vary depending on the mass. In various embodiments, the implantation of various dopant species forms a treated region 178t having a depth D2b measuring from the exposed top surface of the third ILD 178 to a bottom of the treated region 178t. The depth D2b of the treated region 178t and the thickness D2a of the third ILD 178 may have a ratio (D2b:D2a) of about 1:1 to about 1:3. In some embodiments, the depth D2b is in a range from about 3 nm to about 10 nm, such as about 5 nm. If the depth D2b is less than 3 nm, the implanted species may not be sufficient to block leakage current in the third ILD 178 due to the presence of [OH] or [H]. On the other hand, if the depth D2b is greater than about 10 nm, the manufacturing cost is increased without significant advantage.

In some embodiments, the treatment process 135 is a process using reactive substance generated from rare gases (e.g., Ar or He) in-situ in a reaction chamber or in the upstream of a reaction chamber (e.g., from a remote plasma generator). In some embodiments, the reactive substance is or includes helium plasma, helium radicals, or atomic helium. In some embodiments, the treatment process 135 is a plasma treatment process. The plasma treatment may be any suitable plasma process, such as a decoupled plasma process, a remote plasma process, or a combination thereof. The plasma may be formed by a capacitively coupled plasma (CCP) source or an inductively coupled plasma (ICP) source driven by an RF power generator. In cases where ICP source is used, the plasma treatment may be performed in a process chamber having a chamber wall, a ceiling, and a plasma source power applicator comprising a coil antenna disposed over the ceiling and/or around the chamber wall. The plasma source power applicator is coupled through an impedance match network to an RF power source, which may use a continuous wave RF power generator or a pulsed RF power generator operating on a predetermined duty cycle. The use of decoupled plasma may be advantageous since the power is separated into a source power, which is a high power supplied to the chamber wall, and a bias power, which is connected to the substrate 102. The source power ionizes the precursors supplied to the process chamber and generates the reactive species in the process chamber. The bias power on the substrate 102 drives the reactive species towards the substrate 102 and thus provides better control of the reaction rate. In one exemplary embodiment, the decoupled plasma process is formed by the ICP source driven by the RF power generator using a tunable frequency ranging from about 2 MHz to about 13.56 MHz, and the chamber is operated at a pressure in a range of about 10 mTorr to about 1 Torr and a temperature of about 25 degrees Celsius to about 500 degrees Celsius for a process time of about 30 seconds to about 2 minutes. The RF power generator is operated to provide power between about 50 watts to about 1000 watts, and the output of the RF power generator is controlled by a pulse signal having a duty cycle in a range of about 20% to about 80%. The bias power may be in a range of about 0.1 kV to about 5 kV, for example about 0.5 kV to about 1 kV.

In some embodiments, which can be combined with any other embodiment(s) of this disclosure, the treatment process 135 is performed so that the dopant species, plasma species, or neutral radical species are extended through the entire thickness of the third ILD 178. In some embodiments, which can be combined with any other embodiment(s) of this disclosure, the treatment process 135 is performed so that the dopant species, plasma species, or neutral radical species are extended through the entire thickness of the third ILD 178 and into the etch stop layer 145. In some embodiments, which can be combined with any other embodiment(s) of this disclosure, the treatment process 135 is performed so that the dopant species, plasma species, or neutral radical species are extended through the third ILD 178, the etch stop layer 145, and into the second ILD layer 176, such as the depth D3 shown in FIG. 20B. In some embodiments, which can be combined with any other embodiment(s) of this disclosure, the treatment process 135 is performed so that the dopant species, plasma species, or neutral radical species are extended through the entire thickness of the third ILD 178, the etch stop layer 145, and the second ILD layer 176, such as the depth D4 shown in FIG. 20B.

In some embodiments, the treatment process 135 is selectively performed on the third ILD 178 through the use of a mask, which can be any suitable photomask, to block implantation/plasma exposure in selected areas.

In some embodiments, the treated regions 178t of the third ILD 178, the etch stop layer 145, and the second ILD 176 have dopant species from the treatment process 135 and the implantation process 133. In some embodiments, the dopant species, plasma species, or neutral radical species from the treatment process 135 may have a greater depth (e.g., D2, D3, or D4) than the depth (e.g., implanted depth D1) of the dopant species from the implantation process 133 due to the lighter atomic mass of the dopants used in the treatment process 135.

In FIGS. 21A-21B, an interconnect structure 117 is formed over the semiconductor device structure 100. In some embodiments, the interconnect structure 117 comprises a plurality of intermetal dielectric (IMD) layers 168a-168n, a plurality of conductive features 169a-169n embedded in the plurality of IMD layers, and a plurality of etch stop layers 171a-171n disposed between ILD and IMD layer (e.g., the third ILD 178 and the first IMD layer 168a) and between IMD layers (e.g., the first IMD 168a and the second IMD layer (not shown)). The IMD layers, the conductive features, and the etch stop layers may repeat until a desired number of the IMD layer 168n (e.g., topmost IMD layer in the interconnect structure 117), a desired number of the etch stop layer 171n, and a desired number of the conductive features 169n (e.g., topmost conductive features in the interconnect structure 117) embedded in the IMD layer 168n is achieved. Conductive features (e.g., conductive vias and conductive lines) may be formed using any suitable formation process (e.g., lithography with etching, damascene, dual damascene, or the like). In some embodiments, the steps for forming the conductive features may include forming openings in the respective dielectric layers, depositing a conductive layer in the openings, and subsequently performing a planarization process, such as a CMP process, to remove excess materials of the conductive material overfilling the openings. The conductive layer may be deposited by CVD, PVD, sputtering, electroplating, electroless plating, or other suitable deposition technique.

The IMD layers 168a-n may include or be formed of any suitable dielectric material, such as silicon oxide, a low dielectric constant (low-k) material, or a combination thereof. The low-k material may include fluorinated silica glass (FSG), phosphosilicate glass (PSG), borophosphosilicate glass (BPSG), amorphous fluorinated carbon, Parylene, BCB (bis-benzocyclobutenes), polyimide, SiOxCyHz, or SiOxCy, where x, y and z are integers or non-integers, and/or other future developed low-k dielectric materials. The IMD layers 168a-n may be deposited by a plasma-enhanced CVD (PECVD) process or other suitable deposition technique. The material of the etch stop layers 171a-n is chosen such that etch rates of the etch stop layers 171a-n are less than etch rates of the IMD layers 168a-n. In some embodiments, the etch stop layers 171a-n may include the same material as the etch stop layer 145 described above. The conductive vias/lines (e.g., conductive features 169a-n) may include or be formed of any suitable electrically conductive material, such as W, Ru, Co, Cu, Ti, TiN, Ta, TaN, Mo, Ni, or combinations thereof.

In some embodiments, one or more etch stop layers may be omitted. For example, the IMD layer 168a may be in direct contact with the third ILD 178. This may be advantageous in some cases because the etch stop layer has high dielectric constant. Having fewer etch stop layers can lower the capacitance of the overall device.

In various embodiments, the leakage current between the adjacent conductive features (e.g., conductive feature 180 and the conductive feature 169a) in the third ILD 178 and the ID 168a can be reduced or avoided due to the presence of the treated region 178t of the third ILD 178, as the region 137 shown in FIG. 21B. This holds true even if the distance D9 between the adjacent conductive features (e.g., conductive feature 180 in the third ILD 178 and the conductive feature 169a in the ID 168a) is decreased to about 10 nm or below.

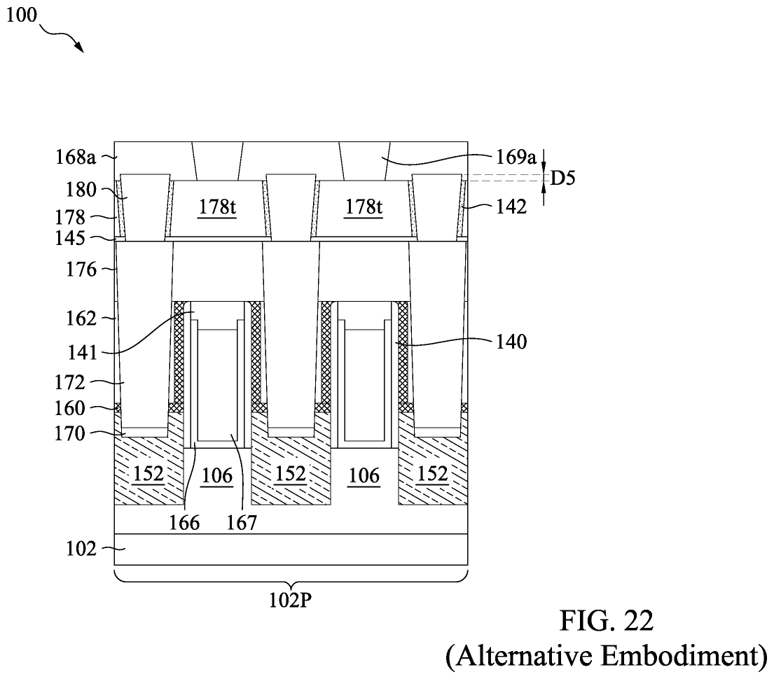

FIG. 22 illustrates a cross-sectional side view of the semiconductor device structure 100 of FIG. 4 taken along cross-section B-B, in accordance with some alternative embodiments. It has been observed that the treatment process 135 may cause the treated regions 178t of the third ILD 178 to shrink or decrease in volume. As a result, the shrinkage of the treated regions 178t in the third ILD 178 may result in an air gap 142 between the third ILD 178 and the conductive features 180. In some embodiments, the top surface of the third ILD 178 is lowered due to the shrinkage of the treated regions 178t in the third ILD 178, resulting in a portion of the conductive features 180 protruded into the ID layer 168a. In some embodiments, the distance D5 between the top surface of the conductive feature 180 in the IMD layer 168 and the top surface of the third ILD 178 may be in a range of about 0.5 nm to about 2 nm, for example about 1 nm.

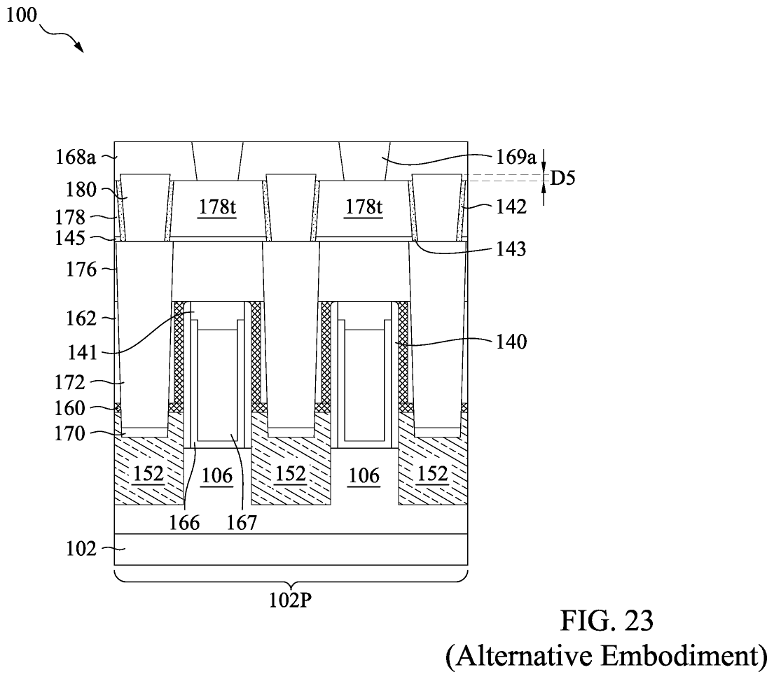

In some embodiments where dopant species, plasma species, or neutral radical species are extended through the entire thickness of the third ILD 178 and into the etch stop layer 145, both the third ILD 178 and the etch stop layer 145 may shrink or decrease in volume, leaving air gaps disposed between the third ILD 178 and the conductive features 180 and the etch stop layer 145 and the conductive features 180. FIG. 23 illustrates a cross-sectional side view of the semiconductor device structure 100 of FIG. 4 taken along cross-section B-B, in accordance with some alternative embodiments. The embodiment of FIG. 23 is substantially identical to that of FIG. 22 except that an air gap 143 is formed between the etch stop layer 145 and the conductive feature 180.

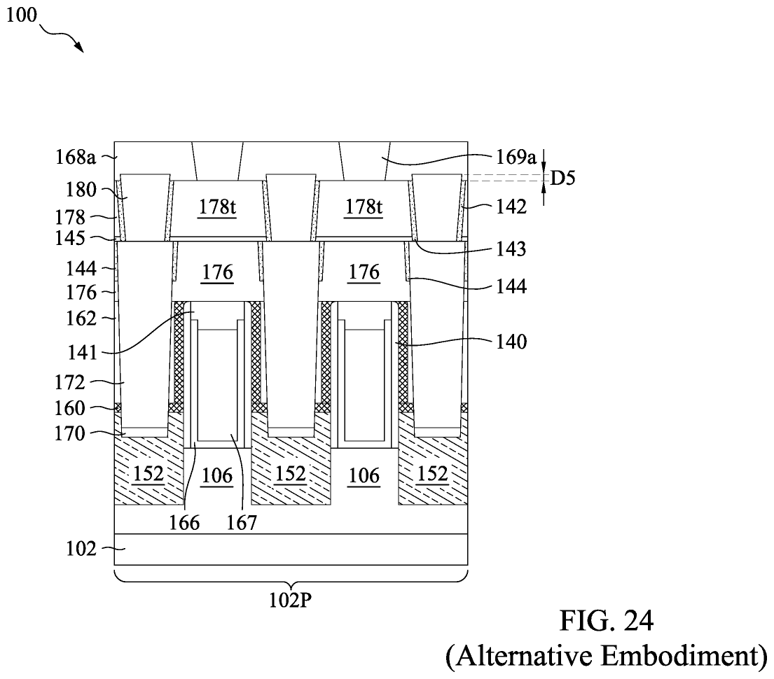

In some embodiments where dopant species, plasma species, or neutral radical species are extended through the third ILD 178, the etch stop layer 145, and into the second ILD layer 176, the third ILD 178, the etch stop layer 145, and a portion of the second ILD 176 may shrink or decrease in volume, leaving air gaps disposed between the third ILD 178 and the conductive features 180, the etch stop layer 145 and the conductive features 180, and the second ILD 176 and the conductive features 180. FIG. 24 illustrates a cross-sectional side view of the semiconductor device structure 100 of FIG. 4 taken along cross-section B-B, in accordance with some alternative embodiments. The embodiment of FIG. 24 is substantially identical to that of FIG. 23 except that an air gap 144 is further formed between the second ILD 176 and the conductive feature 180. Particularly, some portions of the second ILD 176 remain in contact with the conductive feature 180.

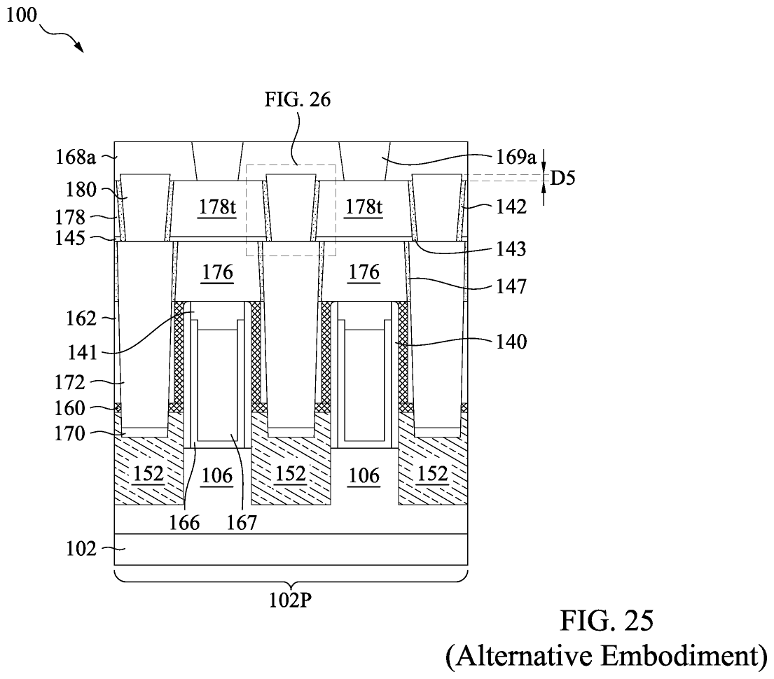

In some embodiments where dopant species, plasma species, or neutral radical species are extended through the entire thickness of the third ILD 178, the etch stop layer 145, and the second ILD layer 176, the third ILD 178, the etch stop layer 145, and the second ILD layer 176 may shrink or decrease in volume, leaving air gaps disposed between the third ILD 178 and the conductive features 180, the etch stop layer 145 and the conductive features 180, and the second ILD 176 and the conductive features 180. FIG. 25 illustrates a cross-sectional side view of the semiconductor device structure 100 of FIG. 4 taken along cross-section B-B, in accordance with some alternative embodiments. The embodiment of FIG. 25 is substantially identical to that of FIG. 24 except that the air gap 147 is extended throughout the region between the etch stop layer 145 and the conductive feature 180.

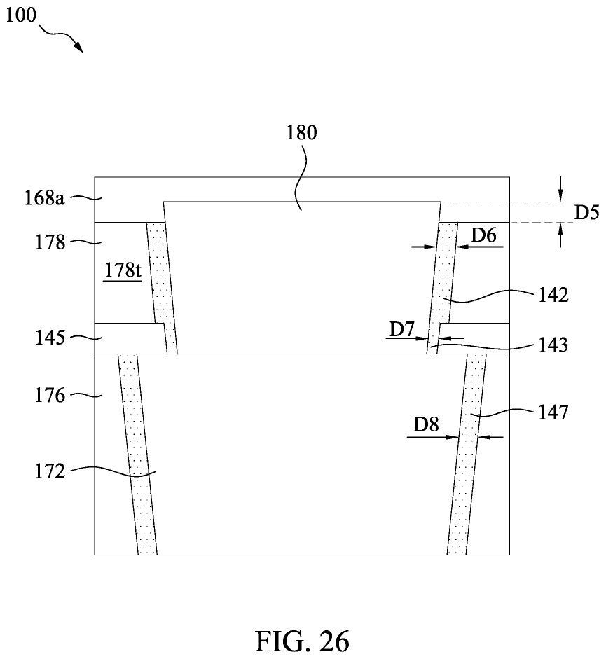

FIG. 26 is an enlarged view of a portion of the semiconductor device structure 100 of FIG. 25. As can be seen, the air gaps 142, 143, 144 are different in size due to different amounts of expansion associated with different materials (i.e., third ILD 178, the etch stop layer 145, and the second ILD 176). In some embodiments, the air gap 142 may have a first gap D6, the air gap 143 may have a second gap D7, and the air gap 147 may have a third gap D8. In some cases, the first gap D6 is greater than the third gap D8. In some cases, the first gap D6 is substantially equal to the third gap D8. In some cases, the first gap D6 is less than the third gap D8. In some cases, the first gap D6 is greater than the second gap D7, and the third gap D8 is greater than the second gap D7.

The present disclosure provides a method for reducing leakage current between adjacent conductive features (e.g., conductive features 180 in an ILD (e.g., third ILD 178) and conductive features 169a in an IMD layer (e.g., IMD layer 168a)) in a semiconductor device structure. In various embodiments, after the via contact (e.g., conductive feature 180) for the S/D contact (e.g., conductive feature 172) is formed, a first treatment process (e.g., implantation process 133) is performed to seal the gap between the via contact and the ILD (e.g., third ILD 178), which prevents subsequent CMP slurries from seeping into and damaging underlying epitaxial S/D features. Then, a CMP process and a second treatment process are sequentially performed on the ILD. The second treatment process may be performed by exposing the ILD to helium-based dopant species, plasma species, or neutral radical species, which reduces [OH] ions in the ILD and minimizes the leakage current. As a result, high performance of integrated circuits (ICs) can be achieved.

An embodiment is a semiconductor device structure. The structure includes a source/drain epitaxial feature disposed over a substrate, a first interlayer dielectric (ILD) disposed over the source/drain epitaxial feature, a second ILD disposed over the first ILD. The second ILD includes a first dopant species having an atomic radius equal to or greater than silicon and a second dopant species having an atomic mass less than 15. The structure also includes a first conductive feature disposed in the second ILD, and a second conductive feature disposed over the source/drain epitaxial feature, the second conductive feature extending through the first ILD and in contact with the first conductive feature.

Another embodiment is a semiconductor device structure. The structure includes a first interlayer dielectric (ILD) disposed over a substrate, a second ILD disposed over the first ILD, an etch stop layer disposed between and in contact with the first and second ILDs, and a first conductive feature disposed in the second ILD. The first conductive feature includes a first portion separated from the second ILD by a first gap, and a second portion separated from the etch stop layer by a second gap less than the first gap. The structure also includes a second conductive feature disposed in the first ILD, the second conductive feature being in contact with the first conductive feature.

A further embodiment is a method for forming a semiconductor device structure. The method includes forming one or more first conductive features in a first interlayer dielectric (ILD), forming an etch stop layer on the first ILD, forming a second ILD over the etch stop layer, forming one or more openings through the second ILD and the etch stop layer to expose a top surface of the one or more first conductive features, filling the one or more openings with a conductive material to form one or more second conductive features, implanting a first group of dopant species into the second ILD, performing a planarization process on the second ILD and the second conductive features, subjecting the second ILD to a treatment process, and forming an intermetal dielectric (IMD) layer on the second ILD, the IMD layer comprises one or more third conductive features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
an epitaxial source/drain feature disposed over a substrate;
a first interlayer dielectric (ILD) disposed over the epitaxial source/drain feature;
a second ILD disposed over the first TLD, the second ILD comprising a first dopant species having an atomic radius equal to or greater than silicon and a second dopant species having an atomic mass less than 15;
a first conductive feature disposed in the second ILD; and
a second conductive feature disposed over the epitaxial source/drain feature, the second conductive feature extending through the first ILD and in contact with the first conductive feature.

2. The semiconductor device structure of claim 1, wherein the first dopant species comprise germanium (Ge), argon (Ar), xenon (Xe), silicon (Si), arsenic (As), or the like, or a combination thereof.

3. The semiconductor device structure of claim 2, wherein the second dopant species comprise helium (He), hydrogen (H), lithium (Li), beryllium (Be), or a combination thereof.

4. The semiconductor device structure of claim 3, wherein the first dopant species are atomic species of germanium and the second dopant species are neutral radical species of helium.

5. The semiconductor device structure of claim 1, the first dopant species have a first depth in the second ILD and the second dopant species have a second depth in the second ILD, and the second depth is greater than the first depth.

6. The semiconductor device structure of claim 1, the first dopant species have a first depth in the second ILD and the second dopant species have a second depth in the second ILD, and the second depth is substantially equal to the first depth.

7. The semiconductor device structure of claim 1, further comprising:
an etch stop layer disposed between the first ILD and the second TLD, wherein the etch stop layer comprises dopant species of helium.

8. The semiconductor device structure of claim 7, wherein the first ILD comprises dopant species of helium.

9. A semiconductor device structure, comprising:
a first interlayer dielectric (ILD) disposed over a substrate;
a second ILD disposed over the first ILD;
an etch stop layer disposed between and in contact with the first and second ILDs;
a first conductive feature disposed in the second ILD, the first conductive feature comprising:
a first portion separated from the second ILD by a first gap; and
a second portion separated from the etch stop layer by a second gap less than the first gap; and
a second conductive feature disposed in the first ILD, the second conductive feature being in contact with the first conductive feature.

10. The semiconductor device structure of claim 9, further comprising:
a third ILD disposed over the second TLD,
wherein the first conductive feature further comprises a third portion extending into the third ILD.

11. The semiconductor device structure of claim 9, wherein the second conductive feature is separated from the first ILD by a third gap.

12. The semiconductor device structure of claim 11, wherein the third gap is substantially equal to the first gap.

13. The semiconductor device structure of claim 11, wherein the third gap is greater or less than the first gap.

14. The semiconductor device structure of claim 9, wherein the second ILD comprises a first dopant species having an atomic radius equal to or greater than silicon and a second dopant species having an atomic mass less than 15.

15. The semiconductor device structure of claim 14, wherein the first dopant species comprise germanium (Ge), argon (Ar), xenon (Xe), silicon (Si), arsenic (As), or the like, or a combination thereof.

16. The semiconductor device structure of claim 15, wherein the second dopant species comprise helium (He), hydrogen (H), lithium (Li), beryllium (Be), or a combination thereof.

17. The semiconductor device structure of claim 16, wherein the first dopant species are atomic species of germanium and the second dopant species are neutral radical species of helium.

18. The semiconductor device structure of claim 14, the first dopant species have a first depth in the second ILD and the second dopant species have a second depth in the second ILD, and the second depth is greater than the first depth.

19. A method for forming a semiconductor device structure, comprising:
forming one or more first conductive features in a first interlayer dielectric (ILD);
forming an etch stop layer on the first ILD;
forming a second ILD over the etch stop layer;
forming one or more openings through the second ILD and the etch stop layer to expose a top surface of the one or more first conductive features;
filling the one or more openings with a conductive material to form one or more second conductive features;
subjecting the second ILD to a first treatment process to implant a first group of dopant species into the second ILD;
performing a planarization process on the second ILD and the second conductive features;
subjecting the second ILD to a second treatment process to provide a second group of dopant species into the second ILD; and
forming an intermetal dielectric (IMD) layer on the second ILD, the IMD layer comprises one or more third conductive features.

20. The method of claim 19, wherein the first group of dopant species are atomic species of germanium and the second group of dopant species are neutral radical species of helium.
